(19) United States
(12) Patent Application Publication
(10) Pub. No.: US 2004/0175870 A1
(43) Pub. Date: Sep. 9, 2004

(54) METHOD FOR MANUFACTURING A THIN FILM TRANSISTOR

(76) Inventors: Chia-Tien Peng, Hsin-Chu Hsien (TW); Ta-Shun Lin, Taipei City (TW)

Correspondence Address: NAIPO (NORTH AMERICA INTERNATIONAL PATENT OFFICE), P.O. BOX 506, MERRIFIELD, VA, 22116, US

(21) Appl. No.: 10/249,585

(22) Filed: Apr. 22, 2003

(30) Foreign Application Priority Data
Mar. 7, 2003 (TW) 092105009

(51) Int. Cl. H01L 21/00

(52) U.S. Cl. 438/149

(57) ABSTRACT

The present invention concerns a method for manufacturing a thin film transistor on a substrate. An amorphous silicon film is deposited on the substrate. A plasma treatment is used to adjust threshold voltage (Vₜ) of the thin film transistor instead of conventional ion implantation Vₜ adjustment. A crystallizationtreatment is carried out to transform the amorphous silicon film into a polysilicon layer. According toa preferred embodiment of the present invention, to create a negative shift of the threshold voltage of the thin film transistor, oxygen-containing plasma is used at a RF power lower than 500W. To create a positive shift of the threshold voltage of the thin film transistor, ammonia plasma is used.

### BACKGROUND OF INVENTION

1. Field of the Inventionbk

The present invention relates to a method for manufacturing a thin film transistor liquid crystal display (TFT LCD). More specifically, the present invention relates to a method for manufacturing a low temperature polysilicon TFT LCD involving a novel plasma threshold voltage adjustment step.

2. Description of the Prior Art

Liquid crystal displays are found in everything from digital watches to laptop computers. In a relatively short period of time, they've crept from a fascinating novelty item to a technology standard. The applications for a liquid crystal display are extensive, such as mobile phones, digital cameras, video cameras, notebooks, and monitors. Due to the high vision quality requirements and the expansion of new application fields, the LCD is developed toward high quality, high resolution, high brightness, and low price. The low temperature polysilicon thin film transistor (LTPS TFT), having a character of being actively driven, is a break-through in achieving the above objectives.

Please refer to FIG. 1 to FIG. 8. FIG. 1 to FIG. 8 are schematic, cross-sectional diagrams illustrating a prior art method of fabricating an LTPS TFT device 1. As shown in FIG. 1, a transparent substrate 10, which may be made of glass, quartz, or plastic materials, is provided. A buffer layer 12 is deposited on the entire surface of the substrate 10. An amorphous silicon layer 14 is then deposited on the buffer layer 12, followed by a dehydrogenation process known in the art.

As shown in FIG. 2, a crystallization process through methods known in the art such as excimer laser annealing (ELA) or light exposure is carried out to transform the amorphous layer 14 into a polysilicon layer 14″. Thereafter, as shown in FIG. 3, conventional lithographic and etching processes are performed to define the polysilicon layer 14″ into a plurality of polysilicon islands 16. As shown in FIG. 4, an ion implantation process is carried out to implant ions such as boron or phosphorus into the polysilicon islands 16, thereby adjusting the threshold voltage (Vₜ) of the thin film transistors. It is appreciated that, in some cases, the step of adjusting the threshold voltage of the thin film transistors through ion implantation is carried out directly after the deposition of the amorphous silicon layer 14.

As shown in FIG. 5, a photoresist layer 18 is coated and patterned on the polysilicon islands 16 to define NMOS doping regions. An N type ion implantation process such as phosphorus ion implantation is carried out to form source/drain of NMOS thin film transistors. As shown in FIG. 6, a gate insulation layer 22 is deposited over the entire surface of the substrate 10. A photoresist layer 26 is coated and patterned on the gate insulation layer 22 to define PMOS doping regions. A P type ion implantation process such as boron ion implantation is carried out to form source/drain of PMOS thin film transistors.

As shown in FIG. 7, after stripping the photoresist layer 26, an activation process is implemented to activate dopants trapped in the source/drain of the thin film transistors. The activation process not only moves the ions to the correct lattice sites but also repairs the lattice defects incurred from the ion implantation process. As shown in FIG. 8, gates 28 are defined on the gate insulation layer 22 by methods known in the art such as metal sputtering, followed by metal etching.

According to the prior art method as described above, an ion implantation process is needed to adjust the threshold voltage of the thin film transistors. To implement the ion implantation process for adjusting the threshold voltage, expensive ion implantation apparatuses are always necessary, which, in terms, is not cost effective.

### SUMMARY OF INVENTION

It is a primary objective of the present invention to provide a method for manufacturing a thin film transistor, in which specific plasma is used to adjust the threshold voltage of thin film transistor instead of conventional ion implantation method.

To achieve this and other objectives and in accordance with the purpose of the invention, as embodied and broadly described herein, the invention provides a method for manufacturing a thin film transistor. The method comprises providing a substrate, depositing an amorphous silicon layer over the substrate, generating a plasma contacting with the amorphous silicon layer for adjusting threshold voltage of the thin film transistor; and performing a crystallization process to transform the amorphous silicon layer into a polysilicon layer. When the thin film transistor is an N type thin film transistor and the plasma is oxygen-containing plasma, a negative shift of threshold voltage of the N type thin film transistor is observed. When the thin film transistor is a P type thin film transistor and the plasma is hydrogen-containing plasma, a positive shift of threshold voltage of the P type thin film transistor is observed.

According to one preferred embodiment of the present invention, a method for fabricating a low temperature polysilicon thin film transistor (LTPS TFT) is disclosed. The method includes providing a transparent substrate, depositing at least one buffer layer on the substrate, performing a chemical vapor deposition (CVD) process to deposit an amorphous silicon layer on the buffer layer, wherein the CVD process is carried out in a CVD vacuum chamber, in-situ adjusting threshold voltage of the LTPS TFT by contacting the amorphous silicon layer with plasma generated within the CVD vacuum chamber; and performing a crystallization process to transform the amorphous silicon layer into a polysilicon layer.

Other objects, advantages, and novel features of the claimed invention will become more clearly and readily apparent from the following detailed description when taken in conjunction with the accompanying drawings.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings:FIG. 1 to FIG. 8 are schematic, cross-sectional diagrams illustrating a prior art method of fabricating an LTPS TFT.

FIG. 9 to FIG. 15 are schematic, cross-sectional diagrams illustrating one preferred embodiment of the present invention.

FIG. 16 and FIG. 17 illustrate the threshold voltage adjustment curves for respective N type thin film transistor (NTFT) and P type thin film transistor (PTFT) under nitrous oxide (N₂O) plasma treatment.

### DETAILED DESCRIPTION

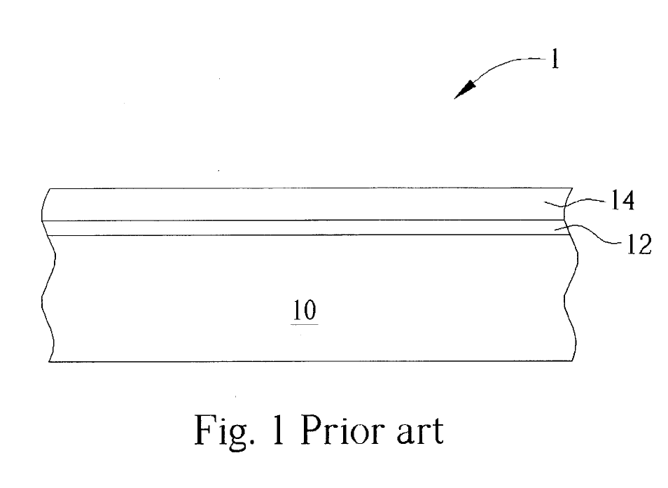

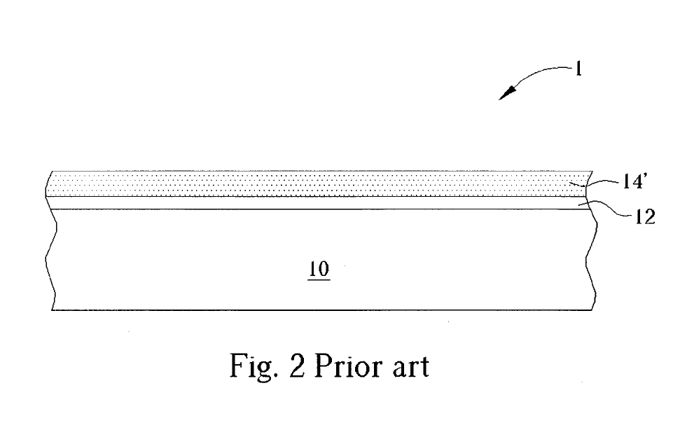

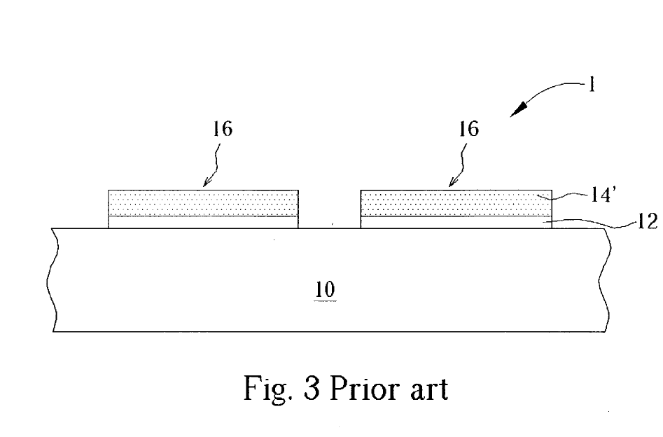

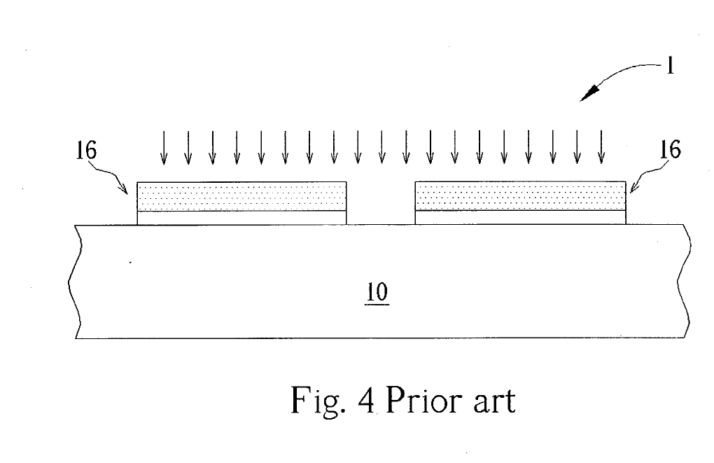

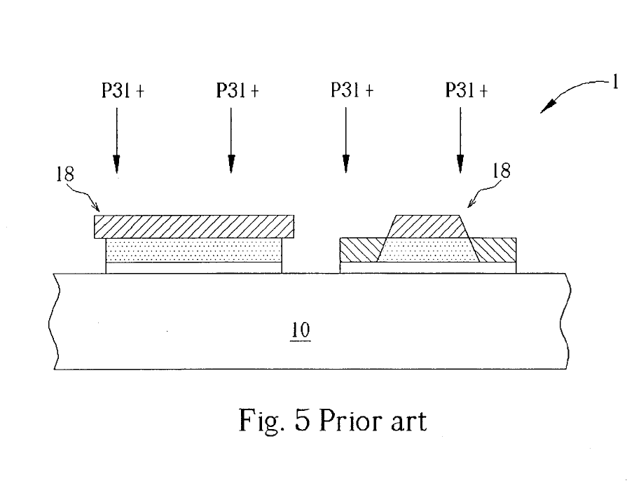

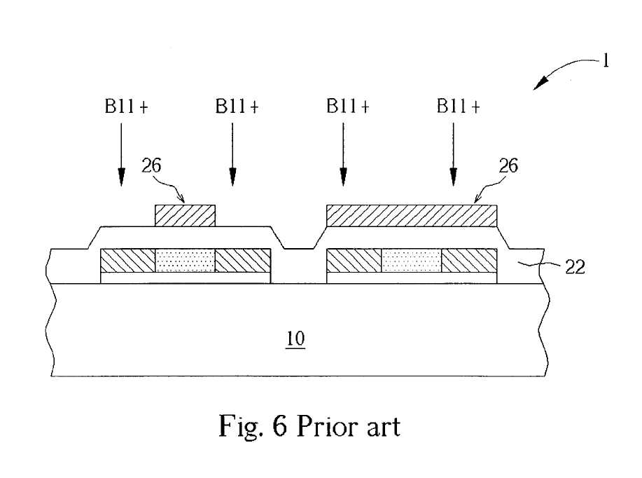

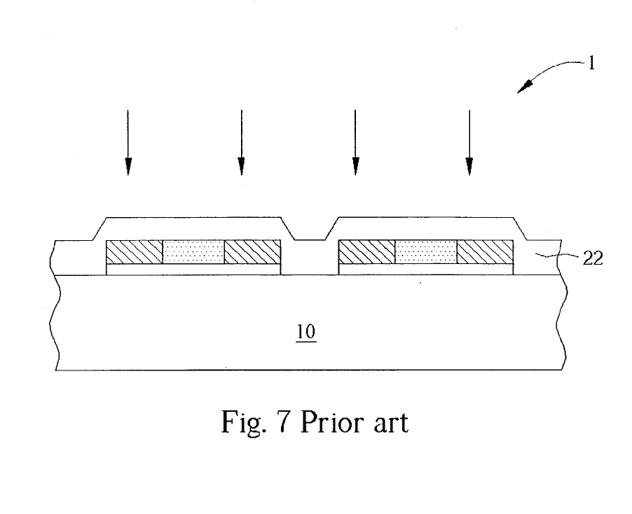

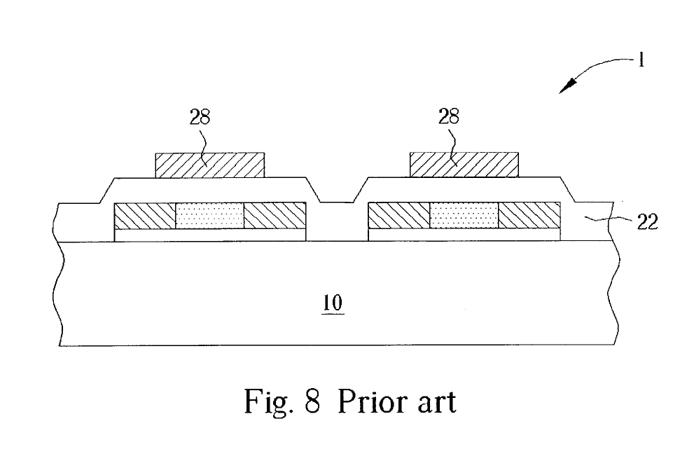

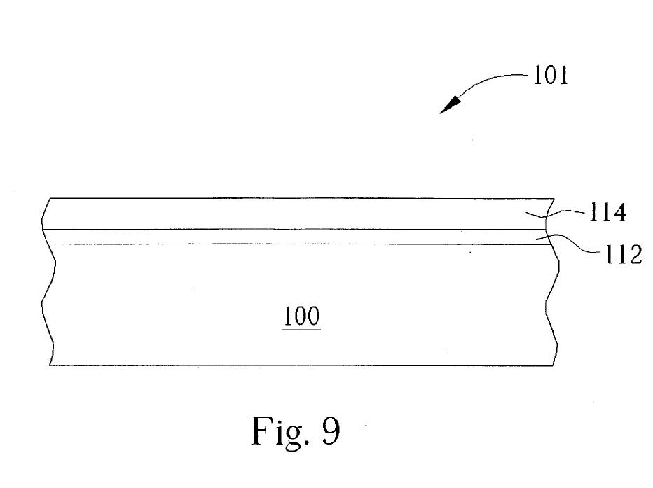

Please refer to FIG. 9 to FIG. 15. FIG. 9 to FIG. 15 are schematic, cross-sectional diagrams illustrating one preferred embodiment of the present invention. As shown in FIG. 9, a transparent substrate 100, which may be made of glass, quartz, or plastic materials, is provided. A buffer layer 112 such as silicon nitride, silicon oxide, or silicon nitride/silicon oxide bi-layer, is deposited on the entire surface of the substrate 100. An amorphous silicon layer 114 is then deposited on the buffer layer 112. According to the preferred embodiment of the present invention, the deposition of the amorphous silicon layer 114 occurs in a vacuum chamber of a plasma-enhanced chemical vapor deposition (PECVD) apparatus (not shown). Thereafter, in the same PECVD vacuum chamber, nitrous oxide (N₂O) plasma is created. It is a crucial step of the present invention to adjust the threshold voltage of the thin film transistors by in-situ contacting the amorphous silicon layer 114 with the nitrous oxide (N₂O) plasma. In accordance with the preferred embodiment of the present invention, the nitrous oxide (N₂O) plasma is created at a nitrous oxide gas flow rate of about 1000 sccm, 380° C., under a radio frequency (RF) power of below 500 W, preferably 100 W. More preferably, the nitrous oxide (N₂O) plasma is tuned to a power density of about 0.078 W/cm² for a standard 40 cm×32 cm panel, at the RF power of 100 W (100 W/(40 cm×32 cm)=0.078 W/cm²).

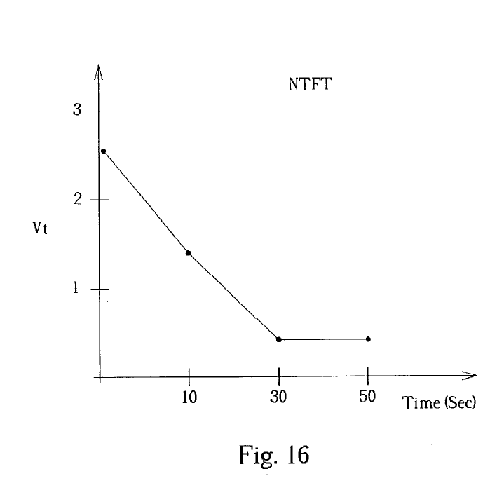

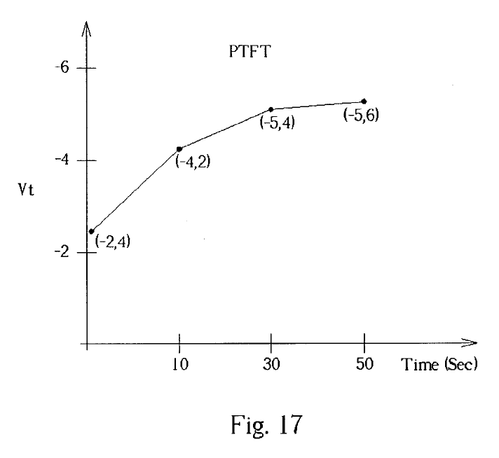

Referring to FIG. 16 and FIG. 17, the threshold voltage adjustment curves for respective N type thin film transistor (NTFT) and P type thin film transistor (PTFT) under the above-mentioned nitrous oxide (N₂O) plasma condition are illustrated. The plots as set forth in FIG. 16 and FIG. 17 both have an X-axis representing process time ranging from 0 second to 50 seconds, which is enough for most applications. As shown in FIG. 16, after treating the surface of the amorphous silicon layer 114 by nitrous oxide (N₂O) plasma described-above for 10 seconds and 50 seconds, the threshold voltage of the NTFT shifts from 2.5 Volts down to 1.4 Volts and to 0.4 Volts (negative shift), respectively. As shown in FIG. 17, after treating the surface of the amorphous silicon layer 114 by nitrous oxide (N₂O) plasma described-above for 10 seconds and 50 seconds, the threshold voltage of the PTFT shifts from −2.4 Volts down to 4.2 Volts and to 5.6 Volts (negative shift), respectively. After adjusting the threshold voltage of the thin film transistors, a conventional dehydrogenation process is carried out.

Although the nitrous oxide (N₂O) plasma is frequently used in semiconductor fabrication processes, applying the nitrous oxide (N₂O) plasma to contact the amorphous silicon to in-situ adjust the threshold voltage of the thin film transistors, which generates unexpected results, is not taught by the prior art. The conventional ion implantation process for threshold voltage adjustment can be omitted according to the present invention. After depositing the amorphous silicon layer 114 on the substrate 100 in the PECVD vacuum chamber, the substrate 100 is subjected to the nitrous oxide (N₂O) plasma without the need of moving the substrate 100 out of the PECVD vacuum chamber, thus the cost can be saved and the throughput is improved.

In accordance with the preferred embodiment of the present invention, to increase the threshold voltage (positive shift) of an NTFT, ammonia (NH₃) plasma is used. Moreover, in addition to nitrous oxide (N₂O) plasma, it is surprisingly found that oxygen plasma can also be used to achieve the purpose of adjusting the threshold voltage of the thin film transistors. It is another advantage of the present invention that because of the short contact of nitrous oxide (N₂O) plasma, a thin silicon oxide only with a thickness of about several angstroms is formed on the amorphous silicon layer 114. The thin silicon oxide facilitates the following amorphous-polysilicon transformation process, thereby generating a polysilicon crystal structure with a larger grain size.

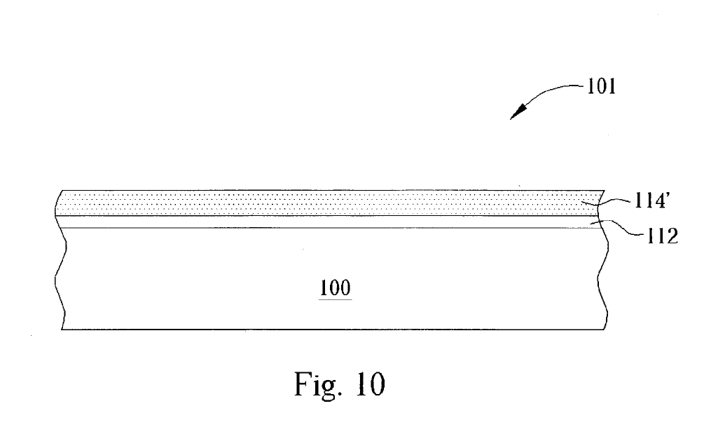

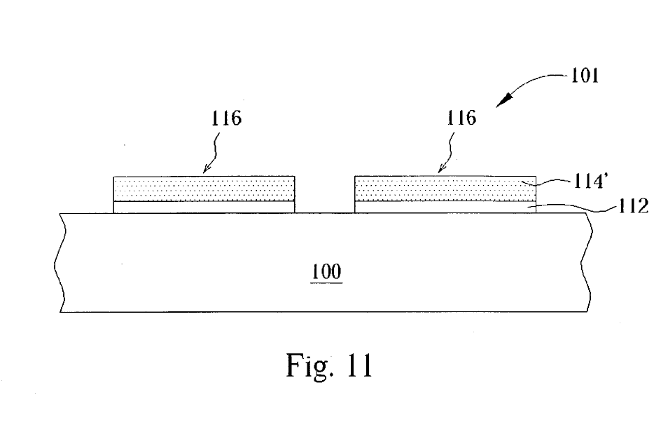

Next, as shown in FIG. 10, a crystallization process through methods known in the art such as excimer laser annealing (ELA) or light exposure is carried out to transform the amorphous layer 114 into a polysilicon layer 114″. According to another preferred embodiment of the present invention, the step of using plasma treatment for adjusting the threshold voltage of the thin film transistors may be carried out after the crystallization process. As shown in FIG. 11, conventional lithographic and etching processes are then performed to define the polysilicon layer 114″ into a plurality of polysilicon islands 116. According to still another preferred embodiment of the present invention, the step of using plasma treatment for adjusting the threshold voltage of the thin film transistors may be carried out after the definition of the polysilicon islands 116.

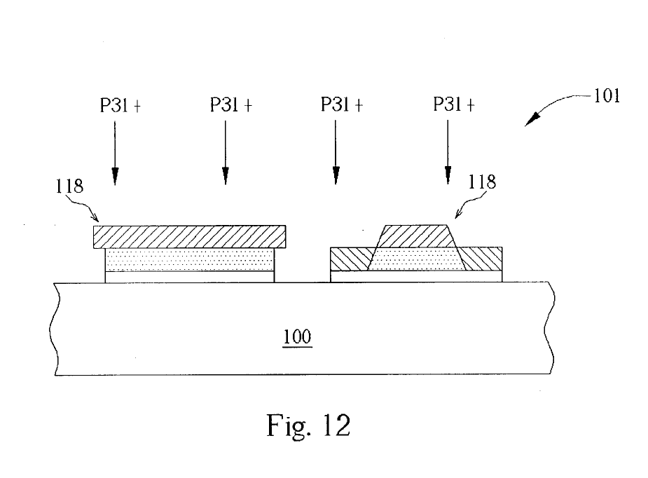

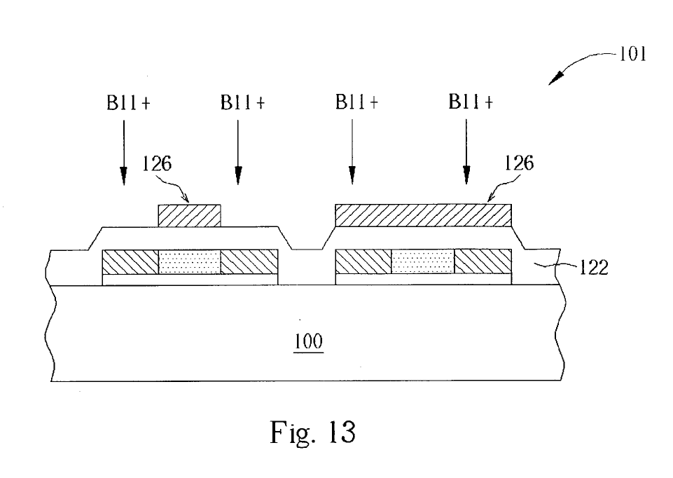

As shown in FIG. 12, a photoresist layer 118 is coated and patterned on the polysilicon islands 116 to define NMOS doping regions. An N type ion implantation process such as phosphorus ion implantation is carried out to form source/drain of NMOS thin film transistors. As shown in FIG. 13, a gate insulation layer 122 is deposited over the entire surface of the substrate 100. A photoresist layer 126 is coated and patterned on the gate insulation layer 122 to define PMOS doping regions. A P type ion implantation process such as boron ion implantation is carried out to form source/drain of PMOS thin film transistors.

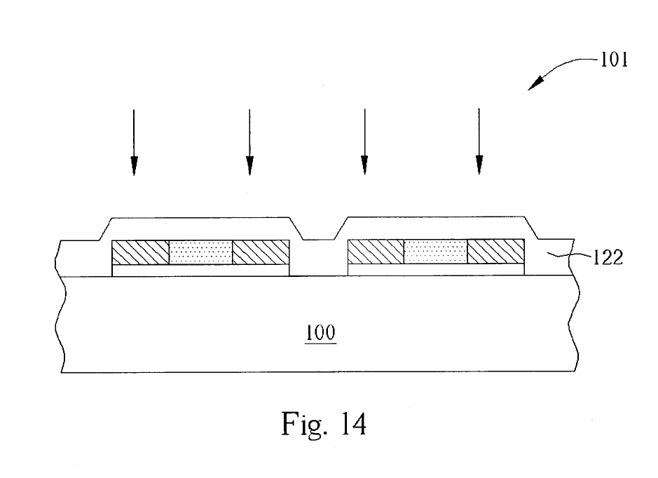

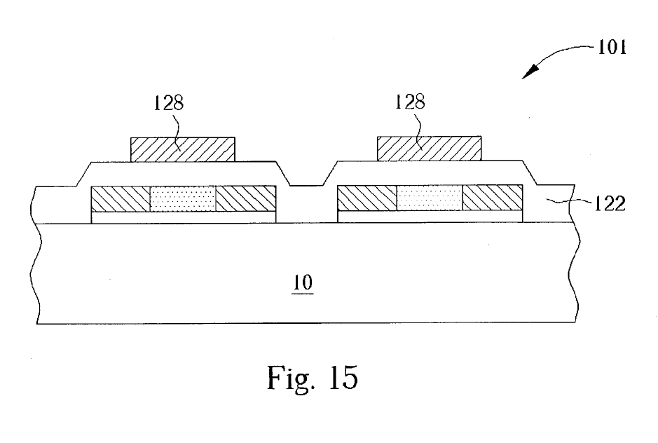

As shown in FIG. 14, after stripping the photoresist layer 126, an activation process is implemented to activate dopants trapped in the source/drain of the thin film transistors. The activation process not only moves the ions to the correct lattice sites but also repairs the lattice defects incurred from the ion implantation process. As shown in FIG. 15, gates 128 are defined on the gate insulation layer 122 by methods known in the art such as metal sputtering, followed by metal etching.

In contrast to the prior art, the present invention uses plasma such as nitrous oxide (N₂O) plasma, oxygen, or ammonia (NH₃) plasma to adjust the threshold voltage of the thin film transistors. When the ammonia (NH₃) plasma is used, a positive shift in the I-V curve is observed. When the nitrous oxide (N₂O) plasma is used, a negative shift in the I-V curve is observed. By tuning the RF power and the process time, the exact shift of the threshold voltage of the thin film transistors can be determined.

Those skilled in the art will readily observe that numerous modifications and alterations of the present invention may be made while retaining the teachings of the invention. Accordingly, the above disclosure should be construed as limited only by the metes and bounds of the appended claims.

What is claimed is:

1. A method for manufacturing a thin film transistor, comprising the steps of:
providing a substrate;
depositing an amorphous silicon layer over the substrate;
generating a plasma contacting with the amorphous silicon layer for adjusting threshold voltage of the thin film transistor; and
performing a crystallization process to transform the amorphous silicon layer into a polysilicon layer.

2. The method according to claim 1 wherein the method further comprises the step of depositing at least one buffer layer on the substrate prior to the step of depositing the amorphous silicon layer over the substrate.

3. The method according to claim 2 wherein the buffer layer comprises a layer of silicon nitride.

4. The method according to claim 2 wherein the buffer layer comprises a layer of silicon oxide.

5. The method according to claim 1 wherein the plasma is oxygen-containing plasma, and wherein contacting the amorphous silicon layer with the oxygen-containing plasma results in a negative shift of the threshold voltage of the thin film transistor.

6. The method according to claim 5 wherein the oxygen-containing plasma is nitrous oxide (N₂O) plasma.

7. The method according to claim 5 wherein the oxygen-containing plasma is oxygen plasma.

8. The method according to claim 1 wherein the plasma is ammonia (NH₃) plasma, and wherein contacting the amorphous silicon layer with the ammonia (NH₃) plasma results in a positive shift of the threshold voltage of the thin film transistor.

9. A method for fabricating a low temperature polysilicon thin film transistor (LTPS TFT), comprising the steps of:
providing a transparent substrate;
depositing at least one buffer layer on the substrate performing a chemical vapor deposition (CVD) process to deposit an amorphous silicon layer on the buffer layer, wherein the CVD process is carried out in a CVD vacuum chamber;
in-situ adjusting threshold voltage of the LTPS TFT by contacting the amorphous silicon layer with plasma generated within the CVD vacuum chamber; and
performing a crystallization process to transform the amorphous silicon layer into a polysilicon layer.

10. The method according to claim 9 wherein the buffer layer comprises a layer of silicon nitride.

11. The method according to claim 9 wherein the buffer layer comprises a layer of silicon oxide

12. The method according to claim 9 wherein the plasma is oxygen-containing plasma, and wherein contacting the amorphous silicon layer with the oxygen-containing plasma results in a negative shift of the threshold voltage of the thin film transistor.

13. The method according to claim 12 wherein the oxygen-containing plasma is nitrous oxide (N₂O) plasma.

14. The method according to claim 12 wherein the oxygen-containing plasma is oxygen plasma.

15. The method according to claim 9 wherein the plasma is ammonia (NH₃) plasma, and wherein contacting the amorphous silicon layer with the ammonia (NH₃) plasma results in a positive shift of the threshold voltage of the thin film transistor.

16. The method according to claim 9 wherein the plasma is generated under a predetermined radio frequency (RF) power.

17. The method according to claim 16 wherein the predetermined RF power is less than 500 W.
